(19) United States
(12) Patent Application Publication
(10) Pub. No.: US 2018/0156234 A1
(43) Pub. Date: Jun. 7, 2018

(54) FAN FRAME BODY STRUCTURE AND FAN WITH THE FAN FRAME BODY

(71) Applicant: ASIA VITAL COMPONENTS CO., LTD., New Taipei City (TW)

(72) Inventors: Bor-Haw Chang, New Taipei City (TW); Yu-Tzu Chen, New Taipei City (TW); Chung-Shu Wang, New Taipei City (TW)

(21) Appl. No.: 15/369,844

(22) Filed: Dec. 5, 2016

(51) Int. Cl. F04D 29/52; F04D 29/54; F04D 19/00; F04D 29/056; H05K 7/20

(52) U.S. Cl. CPC F04D 29/522; F04D 29/545; F04D 19/002; H05K 7/20172; F04D 29/542; H05K 7/20718; F04D 29/056

(57) ABSTRACT

A fan frame body structure and a fan with the fan frame body. The fan frame body structure includes a first fan frame body, a second fan frame body and a connection member. The connection member has a first opening and a second opening. The first and second openings are nonparallel to each other. The first and second fan frame bodies are respectively disposed at the first and second openings. The first and second fan frame bodies are inclined from each other. The first and second fan frame bodies are serially connected in a nonparallel form. Therefore, in the system, due to the resistance of the structure with such configuration, the audio frequency dipole structure is destructed so that the periodical noise and vibration characteristic are lowered.

### BACKGROUND OF THE INVENTION

### 1. Field of the Invention

The present invention relates generally to a fan frame body structure and a fan with the fan frame body structure, and more particularly to a fan frame body structure in which two fan frame bodies are serially connected in a nonparallel form and a fan with the fan frame body structure.

### 2. Description of the Related Art

A fan can provide forced cooling effect. Therefore, the fan is irreplaceably applied to the server of a large-scale storage device to play a decisive role in heat dissipation. A high-performance fan not only can save power, but also can enhance the stability of the operation of the device. Moreover, it has become one of the competitive issues of fan manufacturers how to design low-noise fan products.

In recent years, due to the change of the market and the trend to develop future cloud system, the cloud system has a requirement for the fans that is different from the other fields. First, the performance of the fans applied to the cloud system is required to be 10% or even 15% higher than the other fields. This is because in the cloud and network communication system, the unit operation density is extremely high and the operation conditions of the chassis and the power supply are much stricter than any other environment. Moreover, the operation of the cloud system always 24-hour continues without interruption. Therefore, the requirements of the cloud system for stability, heat dissipation ability and noise control are much higher than a common system.

With respect to a high-density large-scale server, it is necessary to use a fan tray to provide strong airflow for achieving the object of heat dissipation. Therefore, in practice, there is a system of serially connected fan trays. Multiple sets of serially connected fans are further combined in parallel to form a large-scale fan tray system so as to achieve the object of heat dissipation.

In the internal space of the server, the hard disk device such as HDD is generally positioned right in front of the fan tray. The other heat generation components such as the CPU/GPU, DIMMs, memory card or the control panel are positioned right behind the fan tray. In this case, the direction of the flow field is nearly lined up with the respective components. Accordingly, the airflow will flow through the space of the hard disk on the front side into the blades of the heat dissipation fan and then exhaust to the rear side. As a result, the blades of the heat dissipation fan will periodically bear the pulse effect of the non-uniform airflows at the inlet and the outlet. This will make regular dipole noise to create louder periodical noise. The higher the requirement for the performance and heat dissipation effect is, the greater the extent to which the fan is affected by the development of the dipole is and the louder the periodical noise is.

Due to the dipole development of noise, after combined in parallel, the pairs of conventional fans generally will interact on each other to synergize the noise. Therefore, the periodical noise will become more serious. It is therefore tried by the applicant to provide a fan frame body structure and a fan with the fan frame body structure to solve the problem of noise or vibration caused after the fans are serially connected or combined in parallel.

### SUMMARY OF THE INVENTION

It is therefore a primary object of the present invention to provide a fan frame body structure, which can solve the problems of noise and vibration caused after the fans are serially connected or combined in parallel.

It is a further object of the present invention to provide a fan with the fan frame body structure, which can solve the problems of noise and vibration caused after the fans are serially connected or combined in parallel.

To achieve the above and other objects, the fan frame body structure of the present invention includes a first fan frame body, a second fan frame body and a connection member.

The first fan frame body has a first passage and a first bearing cup seat. The first bearing cup seat and the first passage are normal to each other. The second fan frame body has a second passage and a second bearing cup seat. The second bearing cup seat and the second passage are normal to each other. The connection member has a third passage. The third passage has a first opening and a second opening at two ends. The first and second openings are nonparallel to each other. The first and second fan frame bodies are respectively disposed at the first and second openings. The first and second bearing cup seats are inclined from each other.

Still to achieve the above and other objects, the fan frame body structure of the present invention includes a first fan frame body, a second fan frame body and a connection member.

The first fan frame body has a first passage and a first bearing cup seat. The first bearing cup seat is inclined from the first passage. The second fan frame body has a second passage and a second bearing cup seat. The second bearing cup seat and the second passage are normal to each other. The connection member has a third passage. The third passage has a first opening and a second opening at two ends. The first and second openings are parallel to each other. The first and second fan frame bodies are respectively disposed at the first and second openings. The first and second bearing cup seats are inclined from each other.

Still to achieve the above and other objects, the fan frame body structure of the present invention includes a first fan frame body, a second fan frame body and a connection member.

The first fan frame body has a first passage and a first bearing cup seat. The first bearing cup seat and the first passage are normal to each other. The second fan frame body has a second passage and a second bearing cup seat. The second bearing cup seat is inclined from the second passage. The connection member has a third passage. The third passage has a first opening and a second opening at two ends. The first and second openings are parallel to each other. The first and second fan frame bodies are respectively disposed at the first and second openings. The first and second bearing cup seats are inclined from each other.

Still to achieve the above and other objects, the fan frame body structure of the present invention includes a first fan frame body, a second fan frame body and a connection member.

The first fan frame body has a first passage and a first bearing cup seat. The first bearing cup seat is inclined from the first passage. The second fan frame body has a second passage and a second bearing cup seat. The second bearing cup seat is inclined from the second passage. The connection member has a third passage. The third passage has a first opening and a second opening at two ends. The first and second openings are parallel to each other. The first and second fan frame bodies are respectively disposed at the first and second openings. The first and second bearing cup seats are inclined from each other.

Still to achieve the above and other objects, the fan with the fan frame body structure of the present invention includes a first rotor assembly, a first bearing, a first stator assembly, a second rotor assembly, a second bearing and a second stator assembly.

The first rotor assembly has a first fan hub and a first shaft. The first fan hub and the first shaft are normal to each other. The first bearing has a first shaft hole. The first bearing is disposed in the first bearing cup seat. The first shaft is rotatably connected in the first shaft hole.

The first stator assembly has multiple silicon steel sheets and multiple windings wound around the silicon steel sheets. The first stator assembly is fitted around the first bearing cup seat. The second rotor assembly has a second fan hub and a second shaft. The second fan hub and the second shaft are normal to each other. The second bearing has a second shaft hole. The second bearing is disposed in the second bearing cup seat. The second shaft is rotatably connected in the second shaft hole. The second stator assembly has multiple silicon steel sheets and multiple windings wound around the silicon steel sheets. The second stator assembly is fitted around the second bearing cup seat.

In the present invention, the first and second bearing cup seats are arranged in a nonparallel form. Therefore, in the system, due to the resistance of the structure with such configuration, the audio frequency dipole structure is destructed so that the periodical noise and vibration characteristic are lowered.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a perspective exploded view of a first embodiment of the fan frame body structure of the present invention;

FIG. 2 is a sectional assembled view of the first embodiment of the fan frame body structure of the present invention;

FIG. 3 is a sectional assembled view of a second embodiment of the fan frame body structure of the present invention;

FIG. 4 is a sectional assembled view of a third embodiment of the fan frame body structure of the present invention;

FIG. 5 is a sectional assembled view of a fourth embodiment of the fan frame body structure of the present invention;

FIG. 6 is a sectional assembled view of a fifth embodiment of the fan frame body structure of the present invention;

FIG. 7 is a sectional assembled view of a sixth embodiment of the fan frame body structure of the present invention;

FIG. 8 is a sectional assembled view of a seventh embodiment of the fan frame body structure of the present invention;

FIG. 9 is a sectional assembled view of an eighth embodiment of the fan frame body structure of the present invention; and

FIG. 10 is a sectional assembled view of a first embodiment of the fan of the present invention.

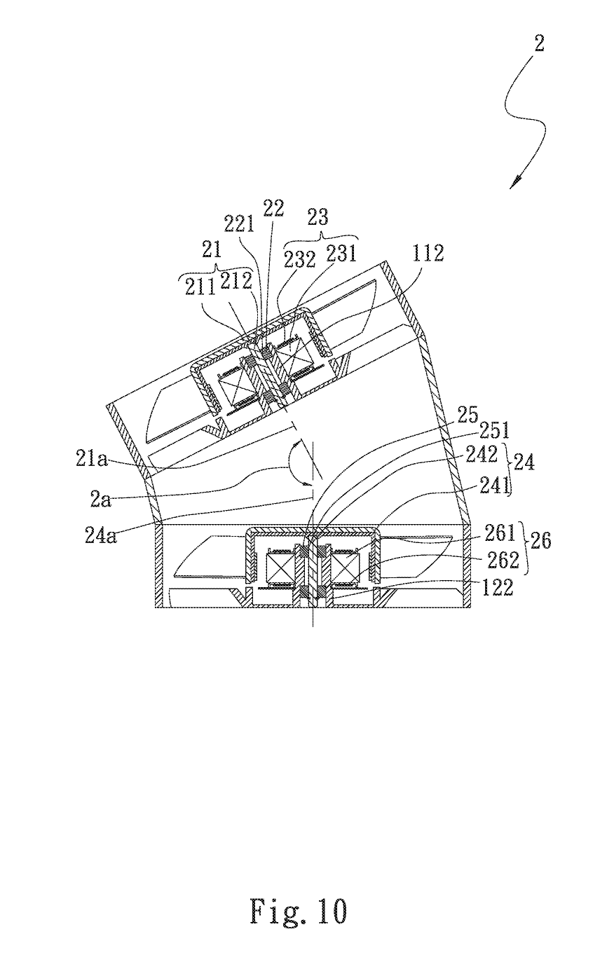

### DETAILED DESCRIPTION OF THE PREFERRED EMBODIMENTS

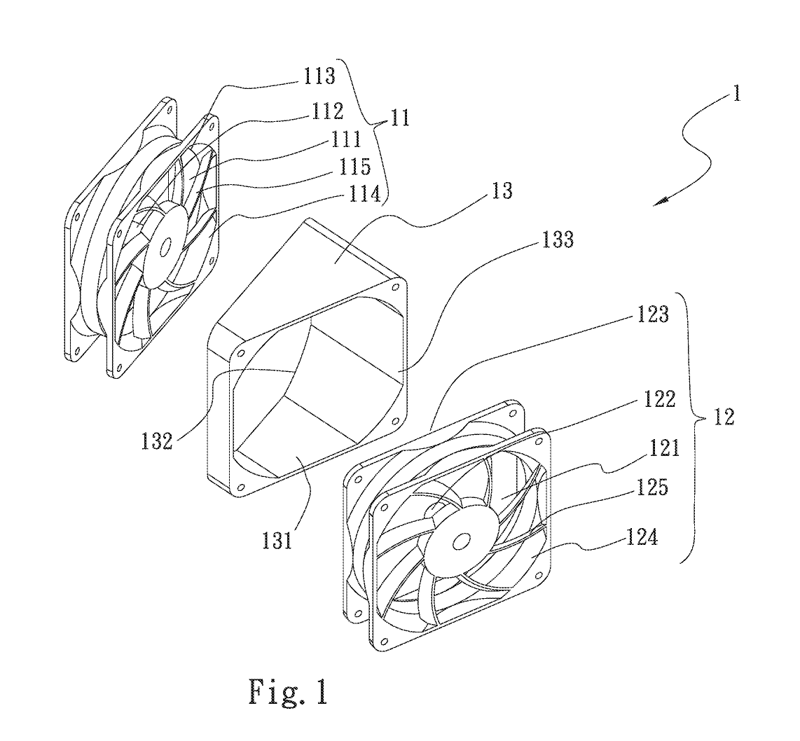

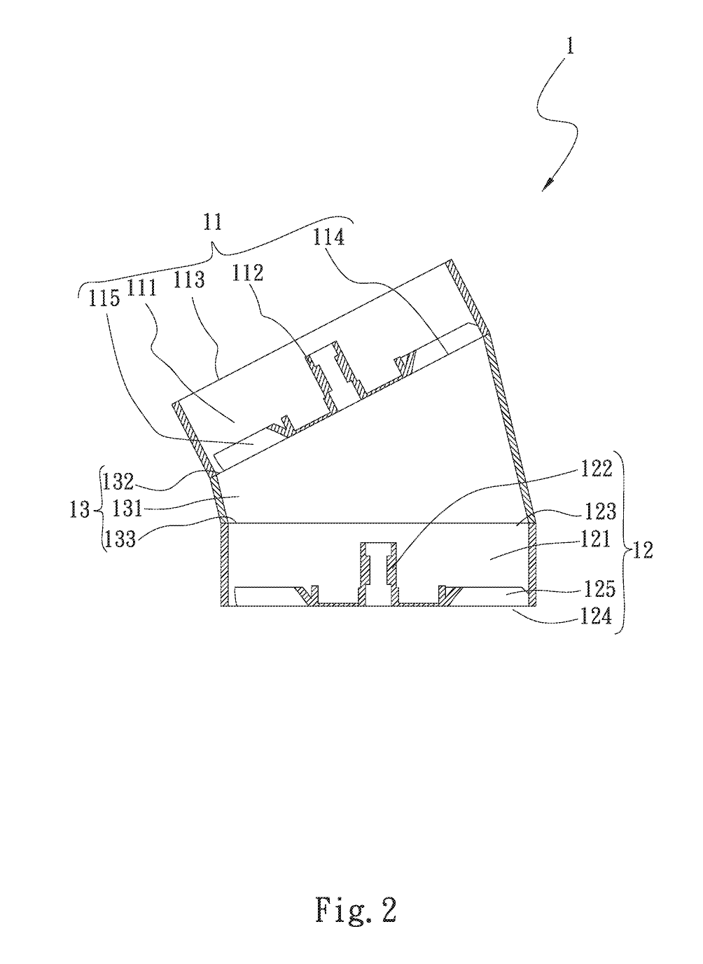

Please refer to FIGS. 1 and 2. FIG. 1 is a perspective exploded view of a first embodiment of the fan frame body structure of the present invention. FIG. 2 is a sectional assembled view of the first embodiment of the fan frame body structure of the present invention. According to the first embodiment, the fan frame body structure 1 of the present invention includes a first fan frame body 11, a second fan frame body 12 and a connection member 13.

The first fan frame body 11 has a first passage 111 and a first bearing cup seat 112. The first bearing cup seat 112 and the first passage 111 are normal to each other. The first passage 111 is formed in the first fan frame body 11.

The second fan frame body 12 has a second passage 121 and a second bearing cup seat 122. The second bearing cup seat 122 and the second passage 121 are normal to each other. The second passage 121 is formed in the second fan frame body 12.

The connection member 13 has a third passage 131. The third passage 131 has a first opening 132 and a second opening 133 at two ends. The first and second openings 132, 133 are nonparallel to each other. The first and second fan frame bodies 11, 12 are respectively disposed at the first and second openings 132, 133. The first and second bearing cup seats 112, 122 are inclined from each other.

The first fan frame body 11 further has a first inlet 113 and a first outlet 114. The first inlet 113 and first outlet 114 are respectively positioned at two ends of the first passage 111. The first outlet 114 is mated with the first opening 132 of the connection member 13. Multiple first connection bodies 115 extend from a circumference of the first bearing cup seat 112. The first connection bodies 115 can be static blades or ribs. The first connection bodies 115 are connected to an inner circumference of the first fan frame body 11. The second fan frame body 12 further has a second inlet 123 and a second outlet 124. The second inlet 123 and second outlet 124 are respectively positioned at two ends of the second passage 121. The second inlet 123 is mated with the second opening 133 of the connection member 13. Multiple second connection bodies 125 extend from a circumference of the second bearing cup seat 122. The second connection bodies 125 can be static blades or ribs. The second connection bodies 125 are connected to an inner circumference of the second fan frame body 12.

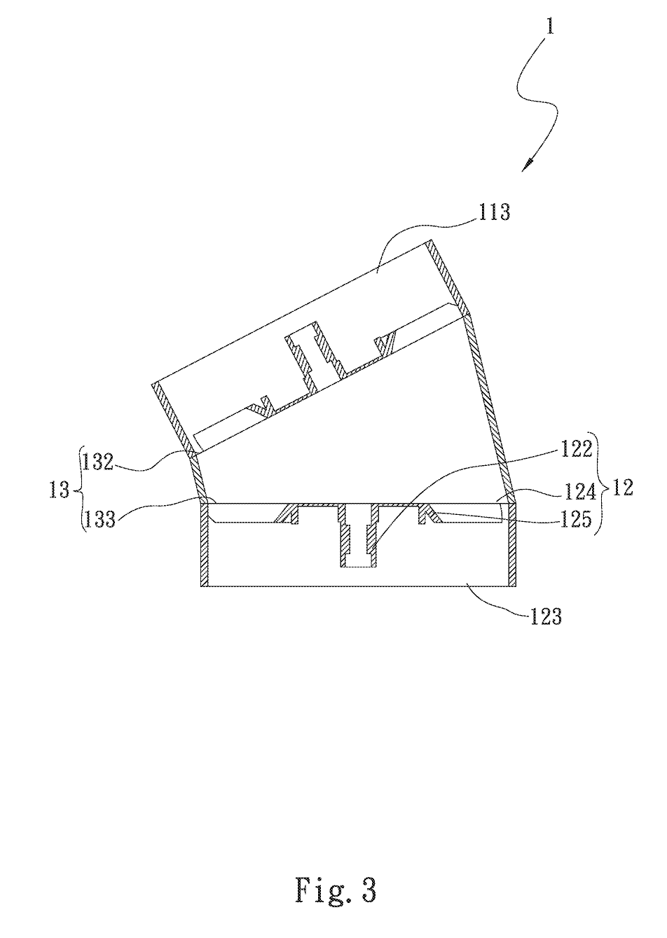

Please now refer to FIG. 3, which is a sectional assembled view of a second embodiment of the fan frame body structure of the present invention. The second embodiment is partially identical to the first embodiment in structure and thus will not be repeatedly described hereinafter. The second embodiment is different from the first embodiment in that the second outlet 124 of the second fan frame body 12 is mated with the second opening 133 of the connection member 13.

Multiple second connection bodies 125 extend from a circumference of the second bearing cup seat 122 to connect with an inner circumference of the second fan frame body 12. That is, the first and second inlets 113, 123 of the first and second fan frame bodies 11, 12 are arranged in reverse directions.

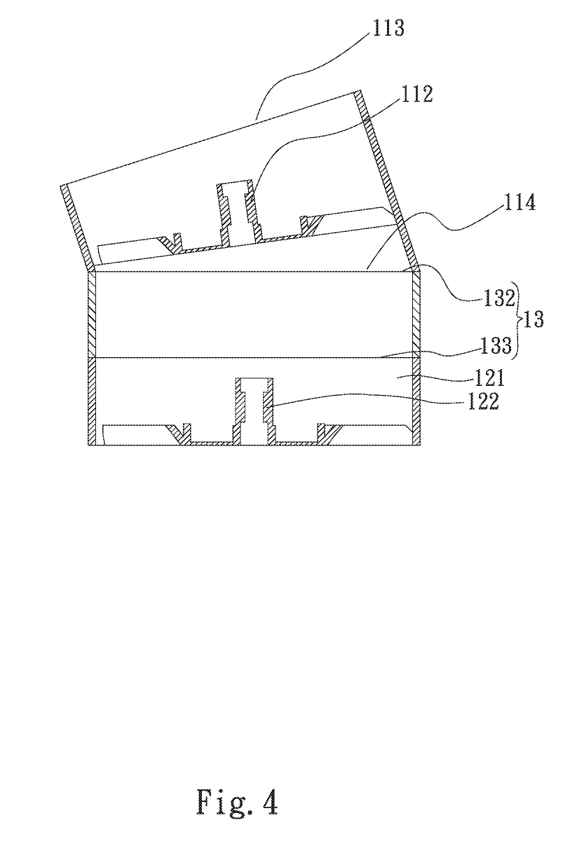

Please now refer to FIG. 4, which is a sectional assembled view of a third embodiment of the fan frame body structure of the present invention. The third embodiment is partially identical to the first embodiment in structure and thus will not be repeatedly described hereinafter. The third embodiment is different from the first embodiment in that the first bearing cup seat 112 is inclined from the first passage 111. The second bearing cup seat 122 is normal to the second passage 121. The first and second openings 132, 133 of the connection member 13 are positioned in parallel to each other.

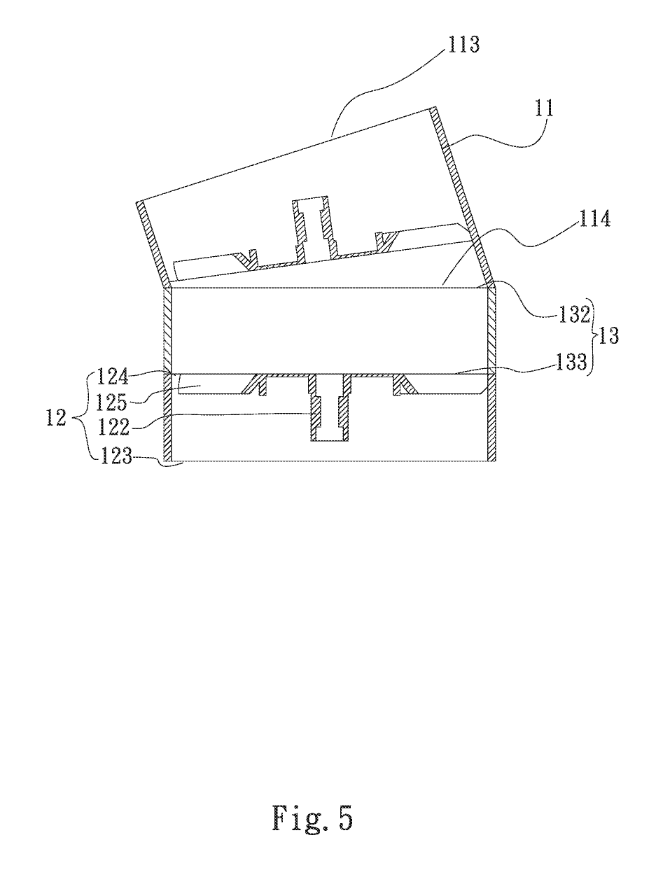

Please now refer to FIG. 5, which is a sectional assembled view of a fourth embodiment of the fan frame body structure of the present invention. The fourth embodiment is partially identical to the third embodiment in structure and thus will not be repeatedly described hereinafter. The fourth embodiment is different from the third embodiment in that the second outlet 124 of the second fan frame body 12 is mated with the second opening 133 of the connection member 13. Multiple second connection bodies 125 extend from a circumference of the second bearing cup seat 122 to connect with an inner circumference of the second fan frame body 12. That is, the first and second inlets 113, 123 of the first and second fan frame bodies 11, 12 are arranged in reverse directions.

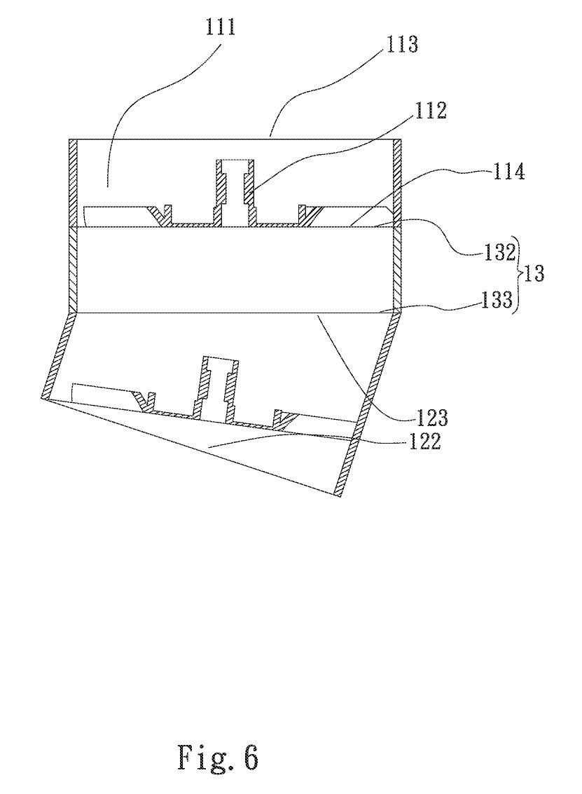

Please now refer to FIG. 6, which is a sectional assembled view of a fifth embodiment of the fan frame body structure of the present invention. The fifth embodiment is partially identical to the first embodiment in structure and thus will not be repeatedly described hereinafter. The fifth embodiment is different from the first embodiment in that the first bearing cup seat 112 is normal to the first passage 111. The second bearing cup seat 122 of the second fan frame body 12 is inclined from the second passage 121. The first and second openings 132, 133 of the connection member 13 are positioned in parallel to each other.

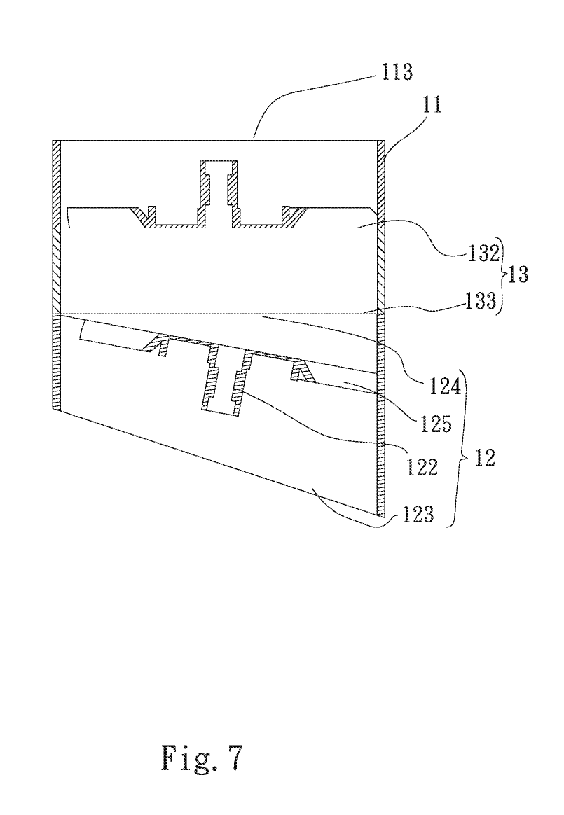

Please now refer to FIG. 7, which is a sectional assembled view of a sixth embodiment of the fan frame body structure of the present invention. The sixth embodiment is partially identical to the fifth embodiment in structure and thus will not be repeatedly described hereinafter. The sixth embodiment is different from the fifth embodiment in that the second outlet 124 of the second fan frame body 12 is mated with the second opening 133 of the connection member 13. Multiple second connection bodies 125 extend from a circumference of the second bearing cup seat 122 to connect with an inner circumference of the second fan frame body 12. That is, the first and second inlets 113, 123 of the first and second fan frame bodies 11, 12 are arranged in reverse directions.

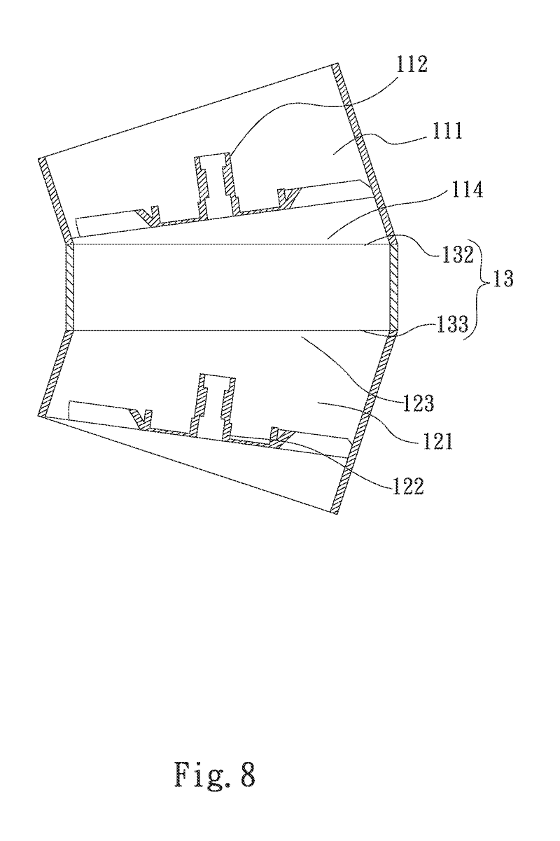

Please now refer to FIG. 8, which is a sectional assembled view of a seventh embodiment of the fan frame body structure of the present invention. The seventh embodiment is partially identical to the first embodiment in structure and thus will not be repeatedly described hereinafter. The seventh embodiment is different from the first embodiment in that the first bearing cup seat 112 is inclined from the first passage 111. The second bearing cup seat 122 is also inclined from the second passage 121. The first and second openings 132, 133 of the connection member 13 are positioned in parallel to each other.

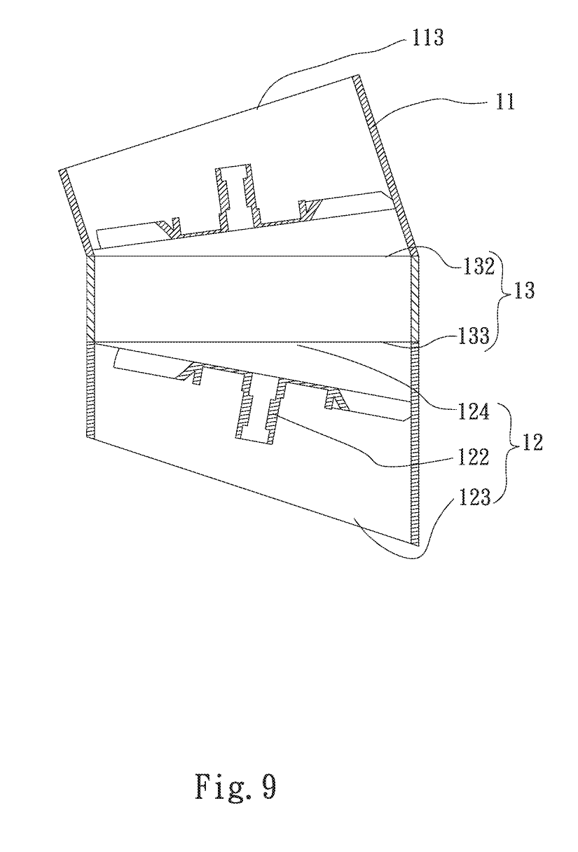

Please now refer to FIG. 9, which is a sectional assembled view of an eighth embodiment of the fan frame body structure of the present invention. The eighth embodiment is partially identical to the seventh embodiment in structure and thus will not be repeatedly described hereinafter. The eighth embodiment is different from the seventh embodiment in that the second outlet 124 of the second fan frame body 12 is mated with the second opening 133 of the connection member 13. Multiple second connection bodies 125 extend from a circumference of the second bearing cup seat 122 to connect with an inner circumference of the second fan frame body 12. That is, the first and second inlets 113, 123 of the first and second fan frame bodies 11, 12 are arranged in reverse directions.

Please now refer to FIG. 9, which is a sectional assembled view of a first embodiment of the fan of the present invention. Also referring to FIGS. 1 to 9, the fan of the present invention includes the fan frame body structure of any of the first to the eighth embodiments of the present invention. The technical characteristics of the above embodiments will not be repeatedly described hereinafter. The fan 2 of the present invention further includes a first rotor assembly 21, a first bearing 22, a first stator assembly 23, a second rotor assembly 24, a second bearing 25 and a second stator assembly 26.

The first rotor assembly 21 has a first fan hub 211 and a first shaft 212. The first fan hub 211 and the first shaft 212 are normal to each other. The first bearing 22 has a first shaft hole 221. The first bearing 22 is disposed in the first bearing cup seat 112. The first shaft 212 is rotatably connected in the first shaft hole 221. The first stator assembly 23 has multiple silicon steel sheets 231 and multiple windings 232 wound around the silicon steel sheets 231. The first stator assembly 23 is fitted around the first bearing cup seat 112.

The second rotor assembly 24 has a second fan hub 241 and a second shaft 242. The second fan hub 241 and the second shaft 242 are normal to each other. The second bearing 25 has a second shaft hole 251. The second bearing 25 is disposed in the second bearing cup seat 122. The second shaft 242 is rotatably connected in the second shaft hole 251. The second stator assembly 26 has multiple silicon steel sheets 261 and multiple windings 262 wound around the silicon steel sheets 261. The second stator assembly 26 is fitted around the second bearing cup seat 122.

The first rotor assembly 21 defines a first virtual central line 21a extending toward the second rotor assembly 24. The second rotor assembly 24 defines a second virtual central line 24a extending toward the first rotor assembly 21. The first and second virtual central lines 21a, 24a intersect each other without being parallel to or normal to each other. The first and second virtual central lines 21a, 24a contain an angle 2a ranging from 91° to 179°.

In the above embodiments, the first, second and third passages 111, 121, 131 communicate with each other. The first fan frame body, the connection member and the second fan frame body can be integrally serially securely connected with each other by means of adhesion, press fit, fusion, engagement or locking of locking members.

In the fan frame body structure and the fan with the fan frame body structure of the present invention, the first and second bearing cup seats 112, 122 are disposed in the first and second passages 111, 121 in an inclined state. Alternatively, the connection member 13 is arranged in an inclined state so that the first and second bearing cup seats 112, 122 are nonparallel to each other. The first and second virtual central lines 21a, 24a of the two rotors (the first and second rotor assemblies 21, 24) are serially connected in a nonparallel form. Therefore, the configurations of the airflow inlet and outlet are changed. Due to the resistance of such structure, the audio frequency development of the dipole is destructed so that the periodical noise energy is minified. After serially connected, the fan structure is changed so that the directions of the airflow of the inlet and the outlet of the entire fan are changed. Under such circumstance, the audio frequency property is changed to reduce the periodical interference effect. As a result, the periodical noise is lowered. The structure of the fan of the present invention is optimized to be different from the conventional fan structure. This can change the inherent frequency of the fan as a whole.

The present invention is not limited to one single set of series fan. The present invention can also achieve the same effect for multiple sets of series fans, which are combined in parallel.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A fan frame body structure comprising:
a first fan frame body having a first passage and a first bearing cup seat, the first bearing cup seat and the first passage being normal to each other;
a second fan frame body having a second passage and a second bearing cup seat, the second bearing cup seat and the second passage being normal to each other; and
a connection member having a third passage, the third passage having a first opening and a second opening at two ends, the first and second openings being nonparallel to each other, the first and second fan frame bodies being respectively disposed at the first and second openings, the first and second bearing cup seats being inclined from each other.

2. The fan frame body structure as claimed in claim 1, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second inlet being mated with the second opening of the connection member, multiple second connection bodies extending from a circumference of the second bearing cup seat to connect with an inner circumference of the second fan frame body.

3. The fan frame body structure as claimed in claim 1, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second outlet being mated with the second opening of the connection member, multiple second connection bodies extending from a circumference of the second bearing cup seat to connect with an inner circumference of the second fan frame body.

4. A fan frame body structure comprising:
a first fan frame body having a first passage and a first bearing cup seat, the first bearing cup seat being inclined from the first passage;
a second fan frame body having a second passage and a second bearing cup seat, the second bearing cup seat and the second passage being normal to each other; and
a connection member having a third passage, the third passage having a first opening and a second opening at two ends, the first and second openings being parallel to each other, the first and second fan frame bodies being respectively disposed at the first and second openings, the first and second bearing cup seats being inclined from each other.

5. The fan frame body structure as claimed in claim 4, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second inlet being mated with the second opening of the connection member, multiple second connection bodies extending from a circumference of the second bearing cup seat to connect with an inner circumference of the second fan frame body.

6. The fan frame body structure as claimed in claim 4, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second outlet being mated with the second opening of the connection member, multiple second connection bodies extending from a circumference of the second bearing cup seat to connect with an inner circumference of the second fan frame body.

7. A fan frame body structure comprising:
a first fan frame body having a first passage and a first bearing cup seat, the first bearing cup seat and the first passage being normal to each other;
a second fan frame body having a second passage and a second bearing cup seat, the second bearing cup seat being inclined from the second passage; and
a connection member having a third passage, the third passage having a first opening and a second opening at two ends, the first and second openings being parallel to each other, the first and second fan frame bodies being respectively disposed at the first and second openings, the first and second bearing cup seats being inclined from each other.

8. The fan frame body structure as claimed in claim 7, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second inlet being mated with the second opening of the connection member, multiple second connection bodies extending from a circumference of the second bearing cup seat to connect with an inner circumference of the second fan frame body.

9. The fan frame body structure as claimed in claim 7, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second outlet being mated with the second opening of the connection member, multiple second connection bodies extending from a circumference of the second bearing cup seat to connect with an inner circumference of the second fan frame body.

10. A fan frame body structure comprising:
a first fan frame body having a first passage and a first bearing cup seat, the first bearing cup seat being inclined from the first passage;
a second fan frame body having a second passage and a second bearing cup seat, the second bearing cup seat being inclined from the second passage; and
a connection member having a third passage, the third passage having a first opening and a second opening at two ends, the first and second openings being parallel to each other, the first and second fan frame bodies being respectively disposed at the first and second openings, the first and second bearing cup seats being inclined from each other.

11. The fan frame body structure as claimed in claim 10, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second inlet being mated with the second opening of the connection member, multiple second connection bodies extending from a circumference of the second bearing cup seat to connect with an inner circumference of the second fan frame body.

12. The fan frame body structure as claimed in claim 10, wherein the first fan frame body further has a first inlet and a first outlet, the first inlet and first outlet being respectively positioned at two ends of the first passage, the first outlet being mated with the first opening of the connection member, multiple first connection bodies extending from a circumference of the first bearing cup seat to connect with an inner circumference of the first fan frame body, the second fan frame body further having a second inlet and a second outlet, the second inlet and second outlet being respectively positioned at two ends of the second passage, the second outlet being mated with the second opening of the connection member, multiple second connection bodies extending from a circumference of the second bearing cup seat to connect with an inner circumference of the second fan frame body.

13. A fan with the fan frame body structure as claimed in any of claims 1 to 12, comprising:
a first rotor assembly having a first fan hub and a first shaft, the first fan hub and the first shaft being normal to each other;
a first bearing having a first shaft hole, the first bearing being disposed in the first bearing cup seat, the first shaft being rotatably connected in the first shaft hole;
a first stator assembly having multiple silicon steel sheets and multiple windings wound around the silicon steel sheets, the first stator assembly being fitted around the first bearing cup seat;
a second rotor assembly having a second fan hub and a second shaft, the second fan hub and the second shaft being normal to each other;
a second bearing having a second shaft hole, the second bearing being disposed in the second bearing cup seat, the second shaft being rotatably connected in the second shaft hole; and
a second stator assembly having multiple silicon steel sheets and multiple windings wound around the silicon steel sheets, the second stator assembly being fitted around the second bearing cup seat.
